(19) United States
(12) Patent Application Publication
(10) Pub. No.: US 2024/0329344 A1
(43) Pub. Date: Oct. 3, 2024

(54) SEMICONDUCTOR PACKAGE AND METHOD FOR MANUFACTURING THE SAME

(71) Applicant: Advanced Semiconductor Engineering, Inc., Kaohsiung (TW)

(72) Inventors: Jung Jui KANG, Kaohsiung (TW); Chiu-Wen LEE, Kaohsiung (TW); Shih-Yuan SUN, Kaohsiung (TW); Chang Chi LEE, Kaohsiung (TW); Hung-Chun KUO, Kaohsiung (TW); Chun-Yen TING, Kaohsiung (TW)

(73) Assignee: Advanced Semiconductor Engineering, Inc., Kaohsiung (TW)

(21) Appl. No.: 18/129,769

(22) Filed: Mar. 31, 2023

(51) Int. Cl. G02B 6/43; G02B 6/42; H01L 25/16

(52) U.S. Cl. CPC G02B 6/43; G02B 6/4206; G02B 6/4239; H01L 25/167

(57) ABSTRACT

Semiconductor packages and methods for manufacturing the semiconductor packages are provided. The semiconductor package includes a first electronic element disposed over a first substrate; a second electronic element disposed over a second substrate spaced apart from the first substrate; and a first interconnection element connected to the first electronic element and the second electronic element. The first electronic element extends beyond an edge of the first substrate. The second electronic element extends beyond an edge of the second substrate and towards the first electronic element. The first interconnection element is configured to optically transmit a signal between the first electronic element and the second electronic element.

### 1. TECHNICAL FIELD

The present disclosure generally relates to semiconductor packages and methods for manufacturing the same. More particularly, the present disclosure relates to semiconductor packages including an interconnection element.

### 2. DESCRIPTION OF THE RELATED ART

A monolithic chip (e.g., an application specific integrated circuit (ASIC) chip) includes multiple functional units, such as memory units (e.g., high bandwidth memory (HBM)), processing units (e.g., central processing units (CPU), graphics processing units (GPU), or the like), and/or input/output (I/O) units. As the semiconductor technology nodes advances, it is proposed to separate the multiple functional units into chiplets.

### SUMMARY

In some arrangements, a semiconductor package includes a first electronic element disposed over a first substrate; a second electronic element disposed over a second substrate spaced apart from the first substrate; and a first interconnection element connected to the first electronic element and the second electronic element. The first electronic element extends beyond an edge of the first substrate. The second electronic element extends beyond an edge of the second substrate and towards the first electronic element. The first interconnection element is configured to optically transmit a signal between the first electronic element and the second electronic element.

In some arrangements, a semiconductor package includes a first electronic element disposed over a substrate, and a second electronic element disposed over the substrate. The first electronic element is electrically connected to the second electronic element through the substrate, and the first electronic element is non-electrically connected to an external element.

In some arrangements, a semiconductor package includes a first electronic element disposed over a first substrate; a second electronic element disposed over a second substrate spaced apart from the first substrate; a first interconnection element configured to optically transmit a signal between the first electronic element and the second electronic element; and a cladding material encapsulates the first interconnection element and configured to confine light in the first interconnection element.

### BRIEF DESCRIPTION OF THE DRAWINGS

Aspects of the present disclosure are readily understood from the following detailed description when read with the accompanying figures. It is noted that various structures may not be drawn to scale, and dimensions of the various structures may be arbitrarily increased or reduced for clarity of discussion.

FIG. 1A, FIG. 1B, FIG. 1C, FIG. 1D, FIG. 1E, and FIG. 1F illustrate schematic cross-sectional views of semiconductor packages in accordance with some arrangements of the present disclosure.

FIG. 1G illustrates a schematic cross-sectional view of a substrate in accordance with some arrangements of the present disclosure.

FIG. 2A and FIG. 2B illustrate schematic top views of a semiconductor package in accordance with some arrangements of the present disclosure.

FIG. 3 illustrates a schematic top view of a semiconductor package in accordance with some arrangements of the present disclosure.

FIG. 4A, FIG. 4B, FIG. 4C, FIG. 4D, FIG. 4E, FIG. 4F and FIG. 4G illustrate various stages of a method for manufacturing a semiconductor package in accordance with some arrangements of the present disclosure.

### DETAILED DESCRIPTION

Common reference numerals are used throughout the drawings and the detailed description to indicate the same or similar components. Arrangements of the present disclosure will be readily understood from the following detailed description taken in conjunction with the accompanying drawings.

The following disclosure provides many different arrangements, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

An ASIC chip includes different functional units. When multiple different functional units are integrated into one ASIC chip, the yield may be decreased as the technology node becomes smaller (e.g., below 7 nm). In the technologies of chiplets, different functional units (such as memory units (e.g., HBM), processing units (e.g., CPU, GPU, or the like), and I/O units) are separated into different elements (chiplets) which are then integrated in, on or over one or more substrates. The chiplets disposed relatively close to each other are electrically connected to each other through conductive lines of the substrate for signal communication of shorter distance, while the chiplets disposed relatively distant from each other (e.g., I/O chiplets of different substrates or packages) are electrically connected to each other by an electrically conductive wire (typically, a copper bonding wire) for signal communication of longer distance. However, the effective transmission distance of the copper bonding wire may be insufficient at a higher data rate (e.g., above 100 Gbps), which may causes signal distortion.

The present disclosure relates to semiconductor packages and methods for manufacturing the same. In some arrangements, the semiconductor packages may include an interconnection element having a longer effective transmission distance than the copper bonding wire. The interconnection element may be an optical interconnection element (e.g., an optical fiber) including an optical channel. The optical interconnection element has a longer effective transmission distance (e.g., 1,000 meters for a single mode optical fiber) at a high data rate of 100 Gbps than a copper interconnect element which may have an effective transmission distance of less than 1 meter. With the use of optical interconnection element(s) for long-distance signal transmission and electrical interconnection element(s) for short-distance signal transmission, the semiconductor packages of the present disclosure may improve the signal distortion issue while enhancing the efficiency and performance of the semiconductor packages.

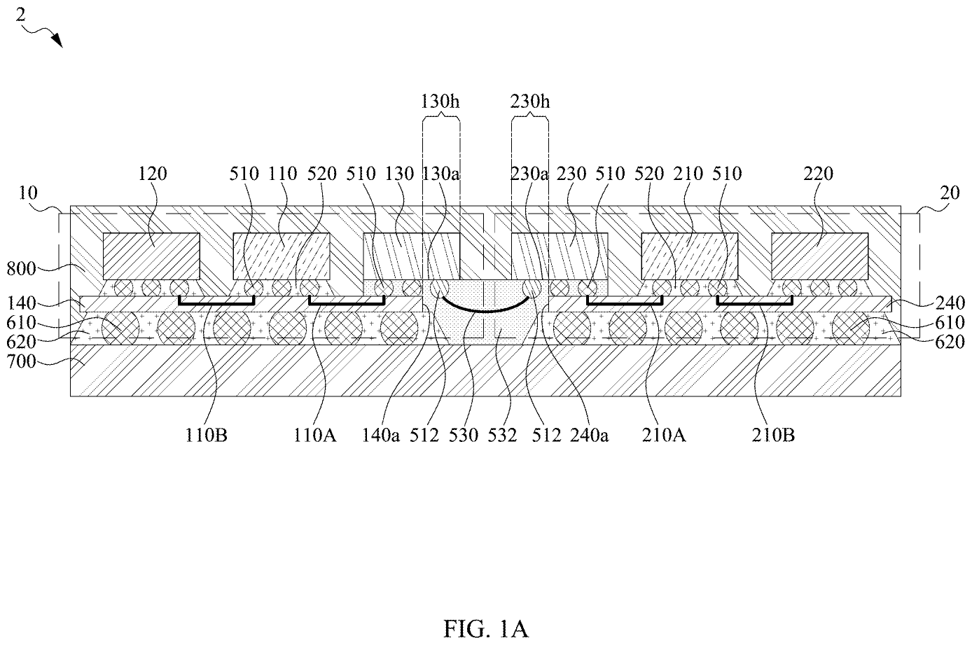

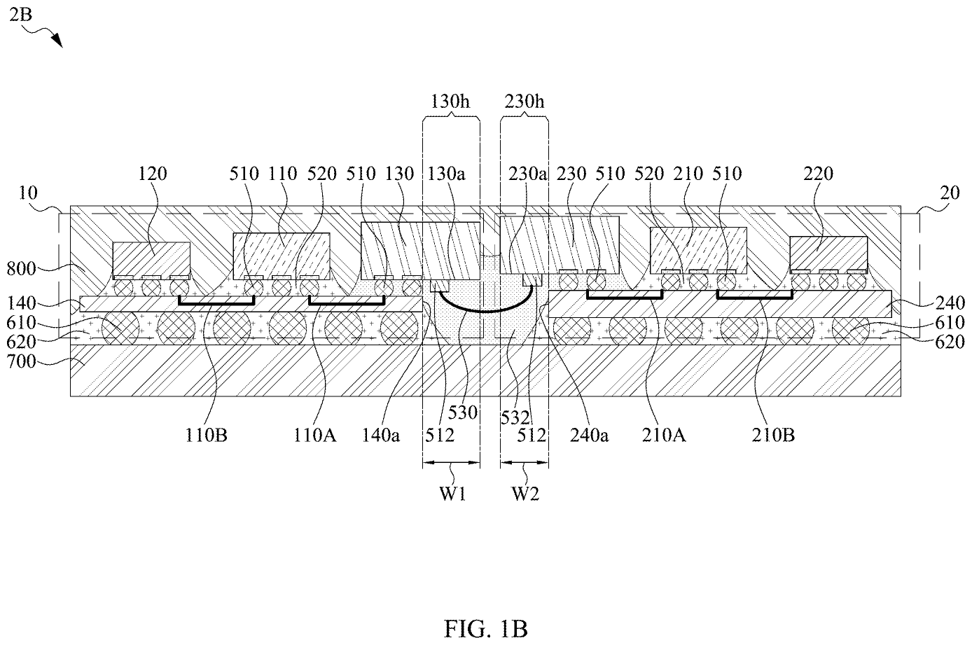

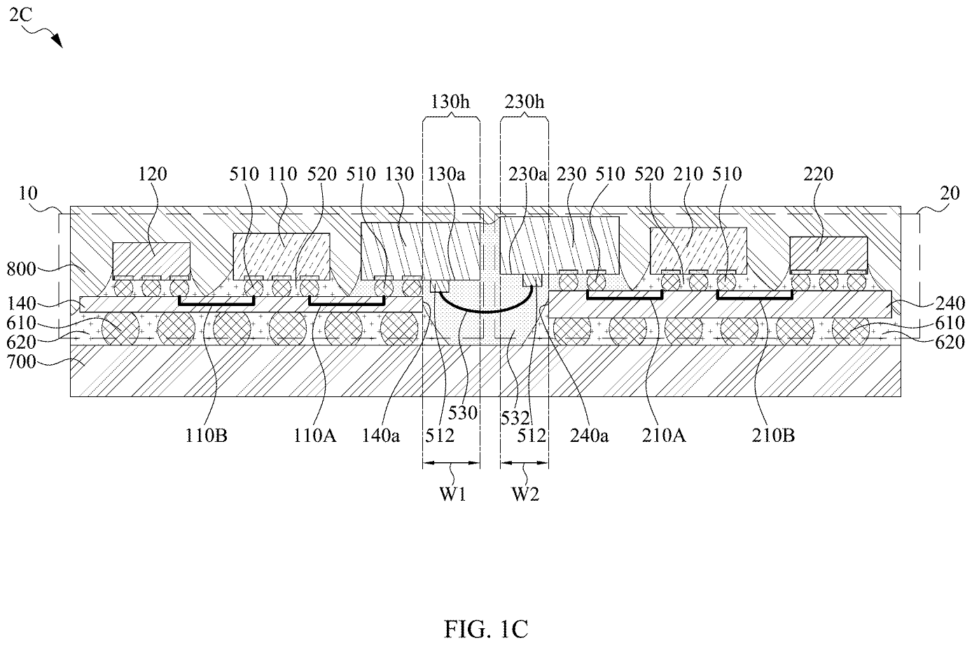

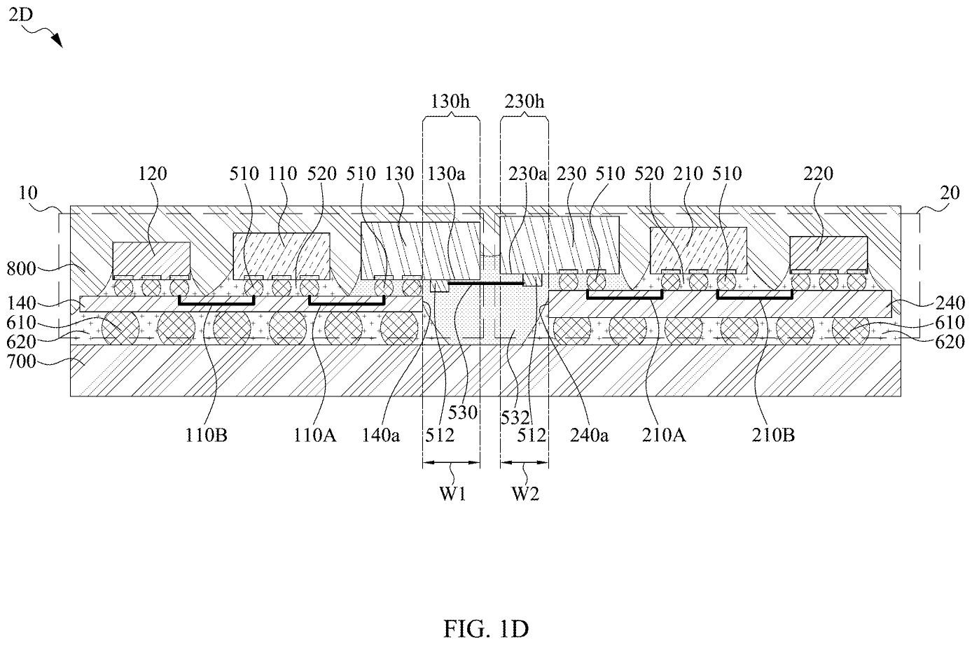

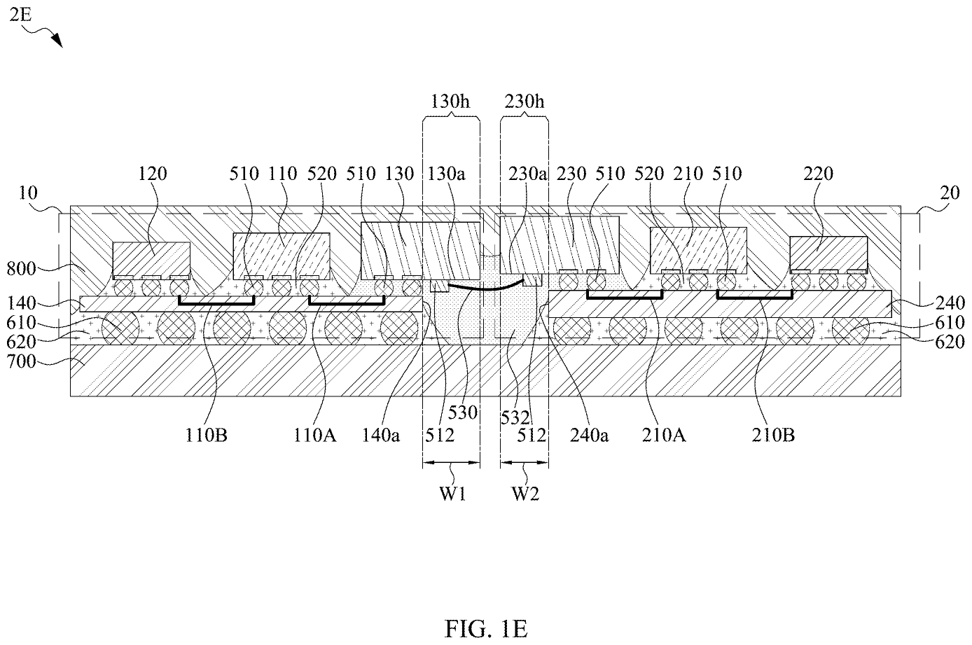

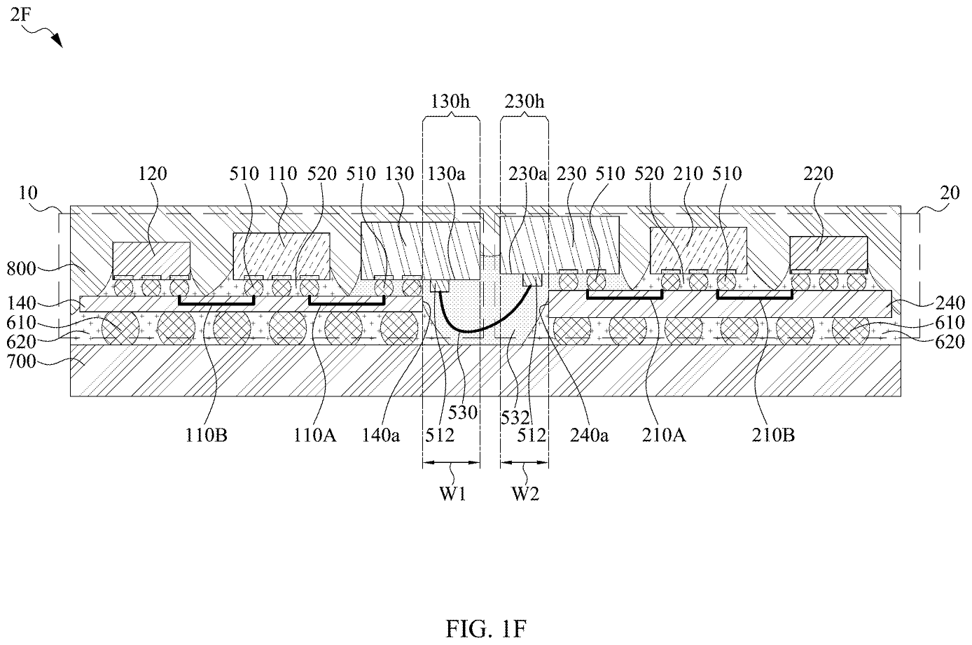

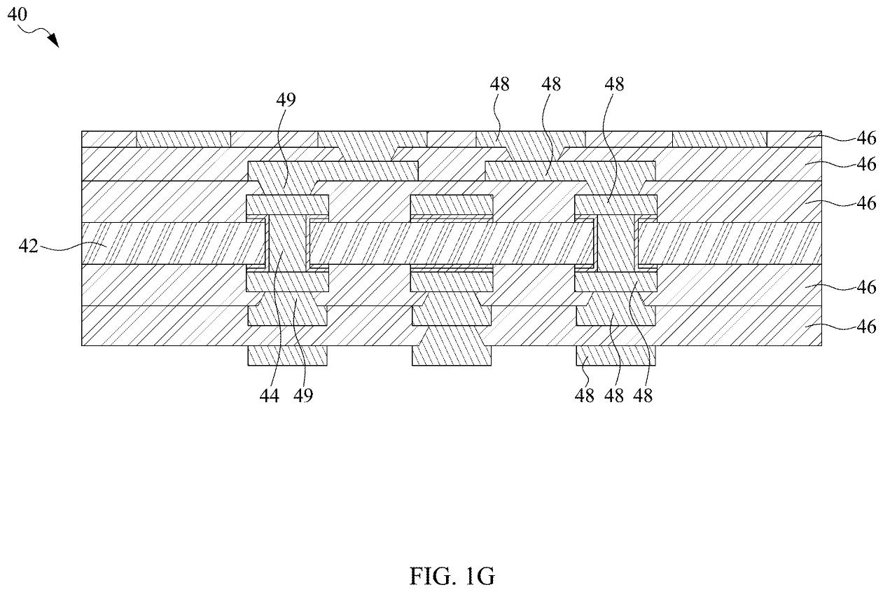

FIG. 1A illustrates a schematic cross-sectional view of a semiconductor package 2 in accordance with some arrangements of the present disclosure. The semiconductor package 2 may include a package 10, a package 20 and an interconnection element 530. The package 10 may include electronic elements 110, 120, 130 and a substrate 140. The package 20 may include electronic elements 210, 220, 230 and a substrate 240. In some embodiments, the semiconductor package which includes one or more packages may be referred to as “semiconductor device.”

The substrates 140 and 240 each may include or be a redistribution structure. The substrates 140 and 240 each may include an interconnection structure (or element), such as an electrical interconnection structure (or element) including a conductive trace, a conductive via, and/or a conductive through via. The substrate 140 and the substrate 240 may be separated or spaced apart from each other. The substrate 140 may include interconnection elements 110A and 110B. The interconnection elements 110A and 110B may be disposed in the substrate 140. The interconnection elements 110A and 110B each may be configured to electrically transmit a signal (e.g., an electrical signal), and may be referred to as an electrical interconnection element. The interconnection elements 110A and 110B each may include an electrically conductive material, such as a metallic material (e.g., copper, nickel, aluminum, copper aluminum, tungsten, titanium, the like, or a combination thereof). The substrate 240 may include interconnection elements 210A and 210B. The interconnection elements 210A and 210B may be disposed in the substrate 240. The interconnection elements 210A and 210B each may be configured to electrically transmit a signal (e.g., an electrical signal), and may be referred to as an electrical interconnection element. The interconnection elements 210A and 210B each may include an electrically conductive material, such as a metallic material (e.g., copper, nickel, aluminum, copper aluminum, tungsten, titanium, the like, or a combination thereof). Each of the interconnection elements 110A, 110B, 210A and 210B may include, for example, a plurality of conductive traces and/or a plurality of conductive vias. In some embodiments, the substrates 140 and 240 may include or be a ceramic substrate, an organic substrate or a semiconductor substrate. In some embodiments, the substrates 140 and 240 each may include or be an interposer, such as a silicon (Si) interposer. The substrates 140 and 240 each may include or be, a printed circuit board, such as a paper-based copper foil laminate, a composite copper foil laminate, or a polymer-impregnated glass-fiber-based copper foil laminate.

The electronic elements 110, 120, 130, 210, 220 and 230 each may be a semiconductor die or chiplet. The electronic elements 110 and 210 each may be configured to process data. The electronic elements 110 and 210 each may include or be a processing element (e.g. a CPU chiplet, a microcontroller unit (MCU) chiplet, a GPU chiplet, an ASIC chiplet, or the like). The electronic elements 120 and 220 each may be configured to store data. The electronic elements 120 and 220 each may include or be a storage or memory element (e.g., a memory chiplet, such as a HBM chiplet, or the like). The electronic elements 130 and 230 each may be configured to perform an input/output (I/O) operation. The electronic elements 130 and 230 each may be configured to perform conversion between an electrical signal and an optical signal. The electronic elements 130 and 230 each may be configured to transmit an electrical signal, an optical signal or both. The electronic elements 130 and 230 each may be also referred to as a photonic element or an optoelectronic element. In some embodiments, the electronic elements 130 and 230 each may be also referred to as a signal transmission element or a signal transmission and conversion element. In some embodiments, the electronic element 130 (or 230) may receive an optical signal (e.g., from the interconnection element 530), convert the optical signal to an electrical signal, and transmit the electrical signal to the substrate 140 (or 240), and vice versa. The electronic elements 130 and 230 each may include or be an I/O element (e.g., an I/O chiplet, such as a photonic I/O chiplet, an integrated photonic I/O chiplet, or the like), such as a photonic I/O element or an optoelectronic I/O element.

In some embodiments, a monolithic electronic element (for example, a processing unit such as an ASIC chip) may include or be divided into a plurality of chiplets, such as the processing elements 110 and 210, the storage or memory elements 120 and 220, and the I/O elements 130 and 230. The monolithic electronic element including the plurality of chiplets may be designed to provide a fully functionality of an independent semiconductor chip (e.g., an ASIC chip). In some embodiments, a portion of the chiplets from the monolithic electronic element is re-grouped to form the package 10, and another portion of the chiplets from the monolithic electronic element is re-grouped to form the package 20. In some embodiments, the chiplets in the packages 10 and 20 that are connected through the interconnection element 530 are packaged to form a fully functional semiconductor package 2.

The electronic elements 110, 120 and 130 may be disposed on or over the substrate 140. The electronic elements 110, 120 and 130 each may be connected (e.g., physically or electrically connected) or bonded to the substrate 140 by connectors 510. Each of the connectors 510 may include or be an electrical bump or a metal bump, such as a solder bump, including a metallic material such as tin (Sn), lead (Pb), silver (Ag), copper (Cu), the like, or a combination thereof. The electrical bump refers to an electrically conductive bump. A filling structure 520 (e.g., an underfill structure) may be formed between the electronic element 110 and the substrate 140 and between the electronic element 120 and the substrate 140 to cover the connectors 510. The filling structure 520 may include an underfill material containing fillers (e.g., an epoxy resin containing silica particles). The electronic element 110 may be electrically connected to the electronic element 130 through the interconnection element 110A. The electronic elements 110 and 130 each may be electrically connected to the interconnection element 110A through the connectors 510. The electronic element 110 may be electrically connected to the electronic element 120 through the interconnection element 110B. The electronic elements 110 and 120 each may be electrically connected to the interconnection element 110B through the connectors 510. The electronic element 130 may be non-electrically connected to an external element outsides the package 10, such as the electronic element 230. A signal transmission between the electronic element 110 and the electronic element 130 is in a way different from a signal transmission between the electronic element 130 and the electronic element 230. In some embodiments, the electronic element 110 and the electronic element 130 are electrically communicated with each other and the electronic element 130 and the electronic element 230 are optically communicated with each other.

The electronic elements 210, 220 and 230 may be disposed on or over the substrate 240. The electronic elements 210, 220 and 230 each may be connected (e.g., physically or electrically connected) or bonded to the substrate 240 by connectors 510. Each of the connectors 510 may include or be an electrical bump or a metal bump, such as a solder bump, as described hereinabove. A filling structure 520 (e.g., an underfill structure) may be formed between the electronic element 210 and the substrate 240 and between the electronic element 220 and the substrate 240 to cover the connectors 510. The electronic element 210 may be electrically connected to the electronic element 230 through the interconnection element 210A. The electronic elements 210 and 230 each may be electrically connected to the interconnection element 210A through the connectors 510. The electronic element 210 may be electrically connected to the electronic element 220 through the interconnection element 210B. The electronic elements 210 and 220 each may be electrically connected to the interconnection element 210B through the connectors 510. The electronic element 230 may be non-electrically connected to an external element outsides the package 20, such as the electronic element 130.

The electronic element 130 has a surface 130a facing the substrate 140. The surface 130a may be an active surface of the electronic element 130. The electronic element 130 may have an overhang 130h relative to the substrate 140. In other words, a portion of a projection of the electronic element 130 in a vertical direction may not overlap the substrate 140. The electronic element 130 may extend beyond a lateral surface 140a of the substrate 140 and towards the electronic element 230. The lateral surface 140a of the substrate 140 may face the substrate 240. The lateral surface 140a of the substrate 140 may be also referred to as an edge of the substrate 140. In addition to the connectors 510, the electronic element 130 may include a connector 512 on the surface 130a. The connector 512 of the electronic element 130 may be located closer to the electronic element 230 than the connector 510 of the electronic element 130 is. The connector 512 may be configured to couple light or an optical signal to or from the electronic element 130. The connector 512 may include or be an optical bump (also referred to as a photonic bump). The optical bump may be configured to transmit light or an optical signal. For example, the optical bump may be configured to emit or receive light or an optical signal. The connector 512 may be connected (e.g., physically and/or optically connected) or bonded to the overhang 130h of the electronic element 130. A projection of the substrate 140 in a vertical direction overlaps the connectors 510 and exposes the connectors 512. The connector 512 may be connected (e.g., physically and/or optically connected) to the interconnection element 530. The electronic element 130 may be connected (e.g., physically and/or optically connected) to the interconnection element 530 (e.g., an optical interconnection element) through the connector 512 (e.g., an optical bump). That is, light or an optical signal can be transmitted between the electronic element 130 and the interconnection element 530 through the connector 512.

The electronic element 230 has a surface 230a facing the substrate 240. The surface 230a may be an active surface of the electronic element 230. The electronic element 230 may have an overhang 230h relative to the substrate 240. In other words, a portion of a projection of the electronic element 230 in a vertical direction may not overlap the substrate 240. The electronic element 230 may extend beyond a lateral surface 240a of the substrate 240 and towards the electronic element 130. The lateral surface 240a of the substrate 240 may face the substrate 140. The lateral surface 240a of the substrate 240 may be also referred to as an edge of the substrate 240. In addition to the connectors 510, the electronic element 230 may include a connector 512 on the surface 230a. The connector 512 of the electronic component 230 may be located closer to the electronic element 130 than the connector 510 of the electronic component 230 is. The connector 512 may be configured to couple light or an optical signal to or from the electronic element 230. The connector 512 may include or be an optical bump (also referred to as a photonic bump). The connector 512 may be connected (e.g., physically and/or optically connected) or bonded to the overhang 230h of the electronic element 230. A projection of the substrate 240 in a vertical direction overlaps the connectors 510 and exposes the connectors 512. The connector 512 may be connected (e.g., physically and/or optically connected) to the interconnection element 530. The electronic element 230 may be connected (e.g., physically and/or optically connected) to the interconnection element 530 (e.g., an optical interconnection element) through the connector 512 (e.g., an optical bump). That is, light or an optical signal can be transmitted between the electronic element 230 and the interconnection element 530 through the connector 512.

Since the I/O surfaces (e.g., 130a and 230a) of the electronic elements 130 and 230 face the substrates 140 and 240 and the electronic elements 130 and 230 overhang the substrates 140 and 240, respectively, the transmission distance between the electronic elements 130 and 230 can be further reduced, thereby enhancing the efficiency of data transmission and reducing the size of the semiconductor package 2.

The interconnection element 530 may be configured to optically transmit a signal (e.g., an optical signal). The interconnection element 530 may include or be an optical interconnection element. The interconnection element 530 may include an optical channel for transmission of light or an optical signal. The interconnection element 530 may include or be a photonic bonding wire. The interconnection element 530 may include or be an optical fiber. The interconnection element 530 may have a curved shape, but the present disclosure is not limited thereto. The interconnection element 530 may have a longer signal transmission path than the interconnection elements 110A. 110B. 210A and 210B. The interconnection element 530 may have a longer effective transmission distance than the interconnection elements 110A, 110B, 210A and 210B. The interconnection element 530 may include a signal transmission medium different from a signal transmission medium of the interconnection elements 110A, 110B, 210A and 210B. The signal transmission medium of the interconnection element 530 may include an organic material, such as a polymeric material (e.g., epoxy). The interconnection element 530 may include a photoresist material, such as an epoxy-based photoresist (e.g., bisphenol A novolac epoxy), but the present disclosure is not limited thereto. The photoresist material may include or be a negative photoresist material. The interconnection element 530 may have a higher data rate than the interconnection elements 110A, 110B, 210A and 210B. The interconnection element 530 may have a greater diameter (or width) than the interconnection elements 110A, 110B, 210A and 210B. The diameter (or width) may be measured in a cross section of the respective interconnection element taken in a direction perpendicular to the respective signal transmission path. The interconnection element 530 may be disposed adjacent to the surface 130a of the electronic element 130 and the surface 230a of the electronic element 230. The interconnection element 530 may be accommodated in a gap between the substrate 140 and the substrate 240. The interconnection element 530 may connect (e.g., physically and/or optically connect) the electronic element 130 and the electronic element 230. Light or an optical signal may be transmitted between the electronic element 130 and the electronic element 230 through the interconnection element 530. The interconnection element 530 may be connected (e.g., physically and/or optically connected) or bonded to the electronic element 130 through the connector 512 of the electronic element 130. The interconnection element 530 may be connected (e.g., physically and/or optically connected) or bonded to the electronic element 230 through the connector 512 of the electronic element 230. That is, in comparison to the interconnection elements 110A and 210A which may be configured to transmit an electrical signal, the interconnection element 530 may be configured to transmit an optical signal.

Since the interconnection element 530 may include a signal transmission medium (e.g., an optical transmission medium) having a longer effective signal transmission distance than a copper bonding wire, a signal transmitted between the electronic element 130 and the electronic element 230, which are disposed relatively distant from each other, can be transmitted with less or no distortion even at a high data bandwidth.

The interconnection element 530 may be covered by a cladding material 532. The interconnection element 530 may be surrounded or encapsulated by the cladding material 532. The interconnection element 530 may be embedded in the cladding material 532. The cladding material 532 may be configured to confine light or an optical signal (or the transmission of light or an optical signal) in the interconnection element 530, for example, by total internal reflection at an interface between the cladding material 532 and the interconnection element 530. In some embodiments, the cladding material 532 is configured to reduce the leakage of light or an optical signal from the interconnection element 530. The cladding material 532 may include any material having a lower refractive index than the interconnection element 530. The cladding material 532 may include or be a reflective material. The cladding material 532 may include a polymeric material, such as a fluoropolymer, but the present disclosure in not limited thereto. The cladding material 530 may cover or surround the connector 512 of the electronic element 130 and the connector 512 of the electronic element 230. The cladding material 532 may also cover or surround the connectors 510 of the electronic element 130 and the connectors 510 of the electronic element 230. Therefore, the cladding material 530 may be also referred to as a filling structure, such as an underfill structure. The cladding material 532 may cover at least a part of the surface 130a of the electronic element 130 and at least a part of the surface 230a of the electronic element 230. The cladding material 532 may fill a gap between the substrate 140 and the substrate 240 and a gap between the filling structure 620 underlying the substrate 140 and the filling structure 620 underlying the substrate 240. The cladding material 532 may contact a lateral surface 140a of the substrate 140 and a lateral surface 240a of the substrate 240. In some embodiments, the cladding material 532 may protect the connectors 510 and 512 and the interconnection element 530 and may be referred to as a protective material or structure.

As shown in FIG. 1A, the semiconductor package 2 may further include a base 700. The base 700 may also be referred to as a carrier or a substrate. The base 700 may include or be, for example, a printed circuit board, such as a paper-based copper foil laminate, a composite copper foil laminate, or a polymer-impregnated glass-fiber-based copper foil laminate. The base 700 may include a ceramic material, an organic substrate, or a metal plate. The base 700 may include an interconnection structure (or element), such as an electrical interconnection structure (or element) including a conductive trace, a conductive via, and/or a conductive through via. The substrates 140 and 240 may be connected (e.g., physically and/or electrically connected) or bonded to the base 700 through connectors 610. Each of the connectors 610 may include or be a metal bump, such as a solder bump, including a metallic material such as tin (Sn), lead (Pb), silver (Ag), copper (Cu), the like, or a combination thereof. A filling structure 620 (e.g., an underfill structure) may be formed between the substrate 140 and the base 700 and between the substrate 240 and the base 700 to cover the connectors 610. The filling structure 620 may include an underfill material containing fillers (e.g., an epoxy resin containing silica particles). The filling structure 620 may be in contact with the cladding material 532. The cladding material 532 may cover a part (e.g., a lateral surface) of the filling structure 620.

Still referring to FIG. 1A, the semiconductor package 2 may further include an encapsulant 800. The encapsulant 800 may include or be a molding compound, but the present disclosure is not limited thereto. The molding compound may include a polymeric material (e.g., epoxy, phenolic, polybutadiene, polyester, the like, or a combination thereof) and other ingredients (such as a filler, a catalyst, a thickener, or a combination thereof), but the present disclosure is not limited thereto. The encapsulant 800 may include a material different from the cladding material 532. The encapsulant 800 may cover or encapsulate the electronic elements 110, 120, 130, 210, 220 and 230. The encapsulant 800 may cover the cladding material 532. The encapsulant 800 may be in contact with the cladding material 532. The encapsulant 800 may cover the underfill structure 520. The encapsulant 800 may cover an upper surface of the substrate 140 and an upper surface of the substrate 240.

FIG. 1B illustrates a schematic cross-sectional view of a semiconductor package 2B in accordance with some arrangements of the present disclosure. The semiconductor package 2B is similar to the semiconductor package 2 as described and illustrated with reference to FIG. 1A, except for at least the following differences. The electronic elements 110, 120, 130, 210, 220 and 230 may have different dimensions (such as thicknesses, widths or footprints). For example, the electronic element 130 may have a greater thickness than the electronic element 110, and the electronic element 110 may have a greater thickness than the electronic element 120, but the present disclosure is not limited thereto. The electronic element 130 may have a greater width (or footprint) than the electronic element 110, and the electronic element 110 may have a greater width (or footprint) than the electronic element 120, but the present disclosure is not limited thereto. The electronic element 230 may have a greater thickness than the electronic element 210, and the electronic element 210 may have a greater thickness than the electronic element 220, but the present disclosure is not limited thereto. The electronic element 230 may have a greater width (or footprint) than the electronic element 210, and the electronic element 210 may have a greater width (or footprint) than the electronic element 220, but the present disclosure is not limited thereto. The substrates 140 and 240 may have different dimensions, such as different thicknesses, widths, or lengths. For example, the substrate 240 may have a greater thickness than the substrate 140, but the present disclosure is not limited thereto. An upper surface of the substrate 240 may not be aligned with an upper surface of the substrate 140. A lower surface of the substrate 240 may not be aligned with a lower surface of the substrate 140. A length W1 by which the electronic element 130 extends beyond the edge 140a of the first substrate 140 may be different from a length W2 by which the electronic element 230 extends beyond the edge 240a of the second substrate 240. That is, the length W1 of the overhang 130h of the electronic element 130 may be different from the length W2 of the overhang 230h of the electronic element 230. For example, the length W1 may be greater than the length W2 as shown in FIG. 1B, but the present disclosure is not limited thereto. The optical bump 512 may be an optical pad or have a shape of a pad. The cladding material 532 may cover at least a part of a lateral surface of the electronic element 130 and/or at least a part of a lateral surface of the electronic element 230. The cladding material 532 may fill in a part of a gap between the electronic element 130 and the electronic element 230. The interface between the cladding material 532 and the encapsulant 800 may be a curved surface, such as a concave surface recessed towards the cladding material 532. The filling structure 520 may cover at least a part of a lateral surface of the electronic element(s) 110, 120, 210 and/or 220. The interface between the filling structure 520 and the encapsulant 800 may be a curved surface, such as a concave surface recessed towards the filling structure 520. The filling structure 620 may cover at least a part of a lateral surface of the substrate(s) 140 and/or 240. The interface between the filling structure 620 and the encapsulant 800 may be a curved surface, such as a concave surface recessed towards the filling structure 620. The interface between the filling structure 620 and the cladding material 532 may be a curved surface, such as a concave surface recessed towards the filling structure 620. The electronic elements 110, 120, 130, 210, 220 and 230 each may include at least one conductive pad electrically connected to the connector 510.

FIG. 1C illustrates a schematic cross-sectional view of a semiconductor package 2C in accordance with some arrangements of the present disclosure. The semiconductor package 2C is similar to the semiconductor package 2B as described and illustrated with reference to FIG. 1B, except that the cladding material 532 fills in the gap between the electronic element 130 and the electronic element 230 to a greater height, for example, up to an upper surface of the electronic element 130 and/or an upper surface of the electronic element 230. The cladding material 532 may be in contact with an upper surface of the electronic element 130 and/or an upper surface of the electronic element 230.

FIG. 1D illustrates a schematic cross-sectional view of a semiconductor package 2D in accordance with some arrangements of the present disclosure. The semiconductor package 2D is similar to the semiconductor package 2B as described and illustrated with reference to FIG. 1B, except that the interconnection element 530 connecting the optical bump (or optical pad) 512 of the electronic element 130 and the optical bump (or optical pad) 512 of the electronic element 230 has a smaller curvature and may be in a shape close to a straight line. In some embodiments, the interconnection element 530 is a substantially straight line. In some embodiments, the interconnection element 530 is a substantially horizontal straight line. A projection of the substrate 140 and/or the substrate 240 in a horizontal direction may expose the interconnection element 530. The interconnection element 530 shown in FIG. 1D has the shortest signal transmission path between the optical bump (or optical pad) 512 of the electronic element 130 and the optical bump (or optical pad) 512 of the electronic element 230, thereby further improving signal transmission performance.

FIG. 1E illustrates a schematic cross-sectional view of a semiconductor package 2E in accordance with some arrangements of the present disclosure. The semiconductor package 2E is similar to the semiconductor package 2B as described and illustrated with reference to FIG. 1B, except that the interconnection element 530 has a smaller curvature and may be slightly curved. A projection of the substrate 140 and/or the substrate 240 in a horizontal direction may expose the interconnection element 530. Compared to the interconnection element 530 shown in FIG. 1A, the interconnection element 530 shown in FIG. 1E has a shorter signal transmission path and therefore can further improve signal transmission performance.

FIG. 1F illustrates a schematic cross-sectional view of a semiconductor package 2F in accordance with some arrangements of the present disclosure. The semiconductor package 2F is similar to the semiconductor package 2B as described and illustrated with reference to FIG. 1B, except that the interconnection element 530 is highly curved. The shape of the interconnection element 530 may be asymmetric. The interconnection element 530 may extend beyond an upper surface of the substrate 140 and/or an upper surface of the substrate 240, or may be further extend beyond a lower surface of the substrate 140 and/or a lower surface of the substrate 240 towards the base 700, thereby increasing contact area of the interconnection element 530 with the cladding material 532 to reduce risk of delamination which may occur between the interconnection element 530 and the cladding material 532 and/or between the interconnection element 530 and the connector 512. Therefore, the yield and performance of the semiconductor package may be further improved.

FIG. 1G illustrates a schematic cross-sectional view of a substrate 40 in accordance with some arrangements of the present disclosure. In some arrangements, the substrate 140 and/or the substrate 240 may have the structure of the substrate 40. The substrate 40 may be a core substrate. The substrate 40 may include a core portion 42, at least one dielectric layer 46, at least one conductive layer 48, at least one conducive via 49, and at least one conductive through via 44. The core portion 42 may be an organic or glass substrate, but the present disclosure is not limited thereto. The conductive through via 44 may penetrate through the core portion 42. The dielectric layers 46, the conductive layers 48, and the conducive vias 49 may be disposed on upper and lower sides of the core portion 42. The conductive through via 44 may be electrically connected to at least one conductive layer 48 on the upper side of the core portion 42 and at least one conductive layer 48 on the lower side of the core portion 42. The conductive layers 48 and the conductive vias 49 may be electrically connected to each other to form an interconnection element, such as the interconnection element 110A, 110B, 210A or 210B. At least one uppermost conducive layer 48 may be electrically connected to an electronic element(s), such as the electronic element(s) 110, 120, 130, 210, 220 and/or 230. At least one lowermost conducive layer 48 may be electrically connected to an electronic element, such as the base 700.

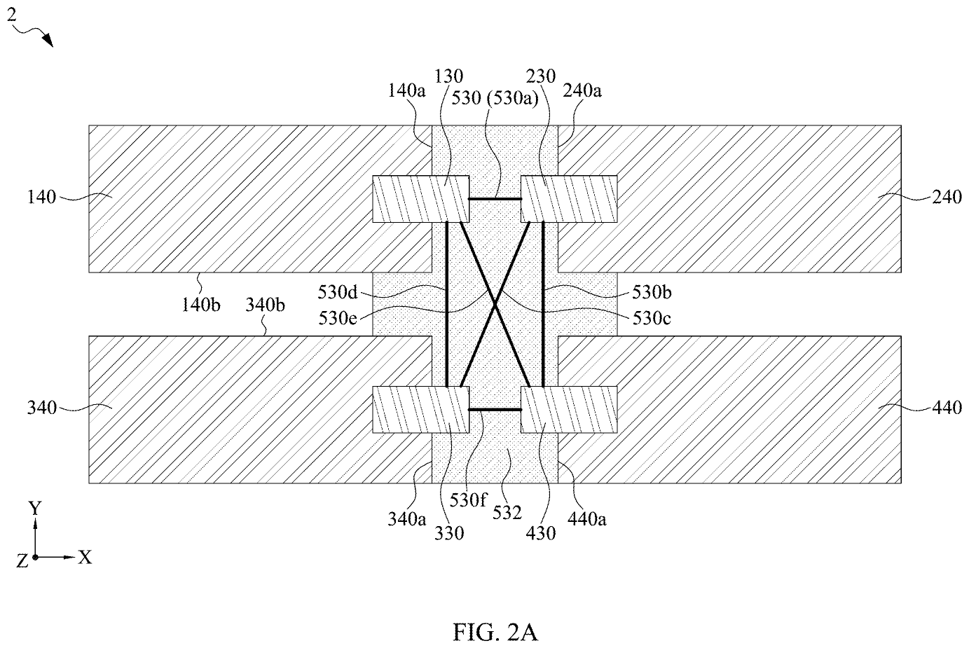

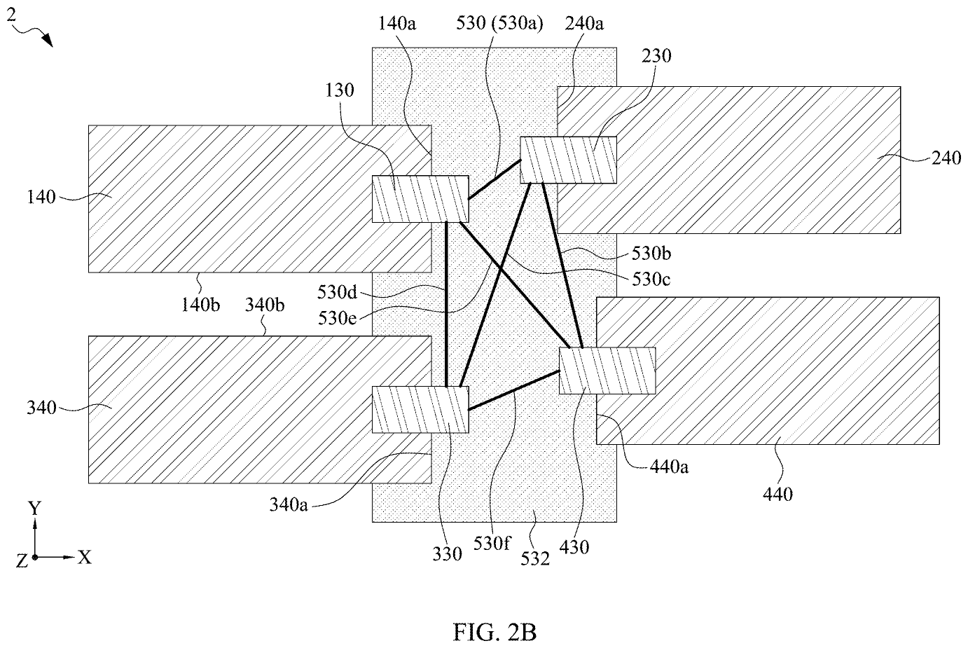

FIG. 2A illustrates a schematic top view of the semiconductor package 2 in accordance with some arrangements of the present disclosure. The semiconductor package 2 may include a plurality of substrates, such as 140, 240, 340 and 440, but is not limited thereto. For clarity, only the substrates 140, 240, 340, 440 (e.g., interposers), the electronic elements 130, 230, 330, 430 (e.g., I/O elements), the interconnection elements 530 (including 530a, 530b, 530c, 530d, 530e and 530f), and the cladding material 532 are shown in FIG. 2A. The arrangements of the electronic elements 130, 230, 330, 430 shown in FIG. 2A are merely for illustration only and may be changed as needed. For example, in some embodiments, more than one electronic element (e.g., more than one electronic element 130) may be disposed on multiple sides of a substrate though not shown in FIG. 2A. As shown in FIG. 2A, the electronic element 130 may be connected to or communicated with the electronic element 230 through the interconnection element 530a, with the electronic element 330 through the interconnection element 530d, and with the electronic element 430 through the interconnection element 530e; the electronic element 230 may be connected to or communicated with the electronic element 130 through the interconnection element 530a, with the electronic element 330 through the interconnection element 530c, and with the electronic element 430 through the interconnection element 530b; the electronic element 330 may be connected to or communicated with the electronic element 130 through the interconnection element 530d, with the electronic element 230 through the interconnection element 530c, and with the electronic element 430 through the interconnection element 530f; and the electronic element 430 may be connected to or communicated with the electronic element 130 through the interconnection element 530e, with the electronic element 230 through the interconnection element 530b, and with the electronic element 330 through the interconnection element 530f. Thus, as illustrated in FIG. 2A, the electronic element (e.g., 130) can be connected to or communicated with the electronic element(s) (e.g., 230 and 330) disposed in the x- or y-direction as well as the electronic element(s) (e.g., 430) disposed in the diagonal direction. In some embodiments, the cladding material 532 may cover the electronic elements 130, 230, 330 and 430 simultaneously. The substrates 140, 240, 340 and 430 may be disposed at different levels (heights), and the interconnection elements 530 can still be connected to the electronic elements 130, 230, 330 and 430 at different levels (heights) for signal communication thereof. Therefore, the structure design can have more possibilities, convenience and flexibility.

FIG. 2B illustrates a schematic top view of the package structure 2 in accordance with some other arrangements of the present disclosure. The top view of FIG. 2B is similar to the top view of FIG. 2A, except for at least the following differences. The substrate 140 may not be aligned with an adjacent substrate (e.g., 240), or the electronic element 130 may not be aligned with an adjacent electronic element (e.g., 230). The substrate 340 may not be aligned with an adjacent substrate (e.g., 440), or the electronic element 330 may not be aligned with an adjacent electronic element (e.g., 430). The substrate 240 may not be aligned with an adjacent substrate (e.g., 140 or 440), or the electronic element 230 may not be aligned with an adjacent electronic element (e.g., 130 or 430). The interconnection elements 530 (including 530a, 530b, 530c, 530d, 530e and 530f) can be connected to the electronic elements 130, 230, 330 and 430 which may not be aligned with each other. Therefore, the structure design can have more possibilities, convenience and flexibility.

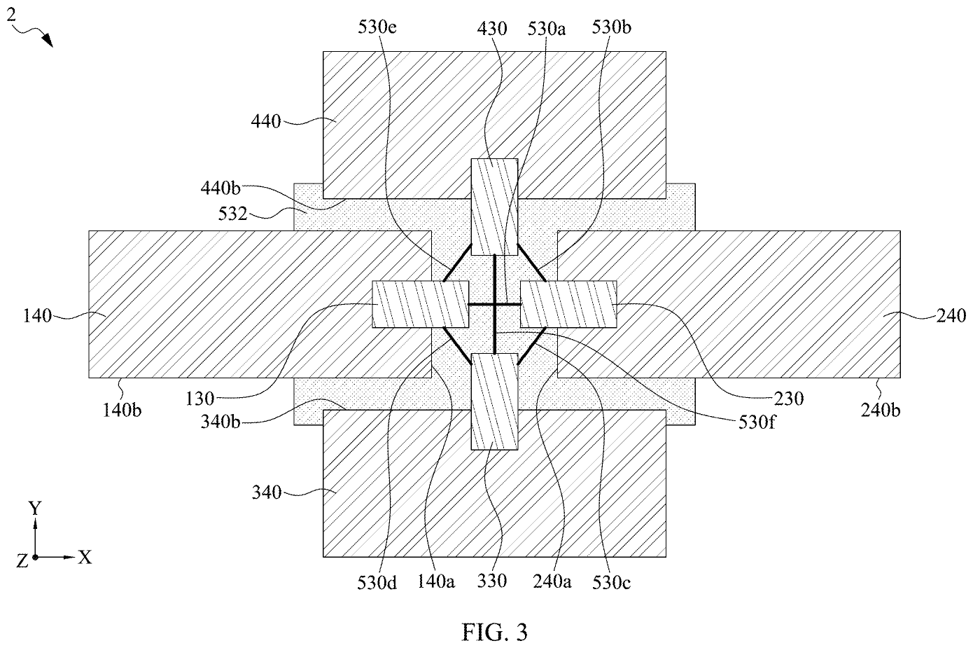

FIG. 3 illustrates a schematic top view of the package structure 2 in accordance with some other arrangements of the present disclosure. The top view of FIG. 3 is similar to the top view of FIG. 2A, except for the following differences. In FIG. 2A the substrates 140, 240, 340 and 440 are arranged such that a short side (e.g., 140a) of a substrate (e.g., 140) is aligned with a short side (e.g., 240a) of an adjacent substrate (e.g., 240) and a long side (e.g., 140b) of the substrate (e.g., 140) is aligned with a long side (e.g., 340b) of another adjacent substrate (e.g., 340); in addition, the electronic elements 130, 230, 330 and 430 overhang from the short sides 140a, 240a, 340a and 440a of the substrates 140, 240, 340 and 440, respectively. In FIG. 3 the substrates 140, 240, 340 and 440 are arranged such that the short side 140a of the substrate 140 is aligned with the short side 240a of the substrate 240, the long side 340b of the substrate 340 is partially aligned with the long side 140b of the substrate 140 and partially aligned with the long side 240b of the substrate 240, and the long side 440b of the substrate 440 is partially aligned with the other long side (not denoted) of the substrate 140 and partially aligned with the other long side (not denoted) of the substrate 240; in addition, the electronic elements 130 and 230 overhang from the short sides 140a and 240a of the substrates 140 and 240, respectively, and the electronic elements 330 and 430 overhang from the long sides 340b and 440b of the substrates 340 and 440, respectively. As compared to FIG. 2A, the arrangement shown in FIG. 3 can allow for shorter signal transmission paths among the electronic elements 130, 230, 330, 430 (e.g., I/O elements), and the density of the interconnection elements 530 per unit area is higher. In some arrangements, the arrangements shown in FIG. 2A, FIG. 2B and FIG. 3 may be combined as needed.

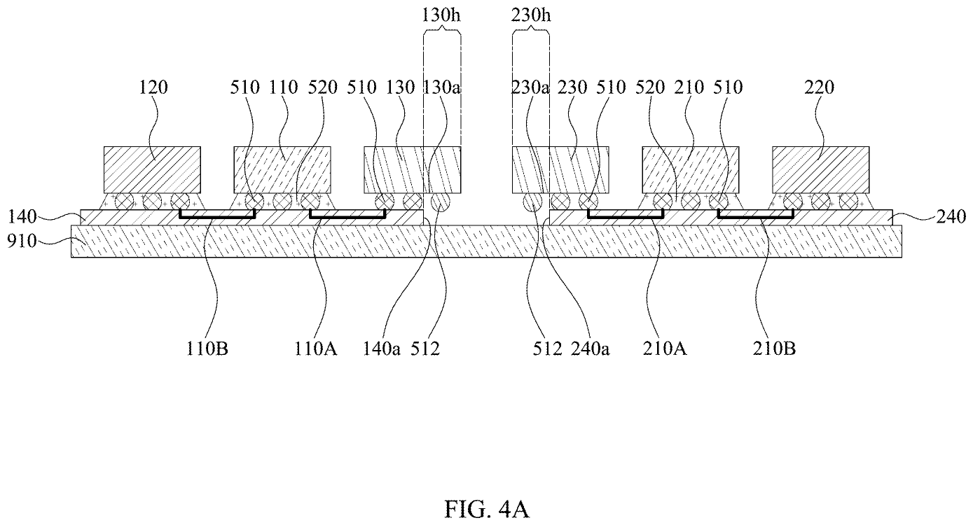

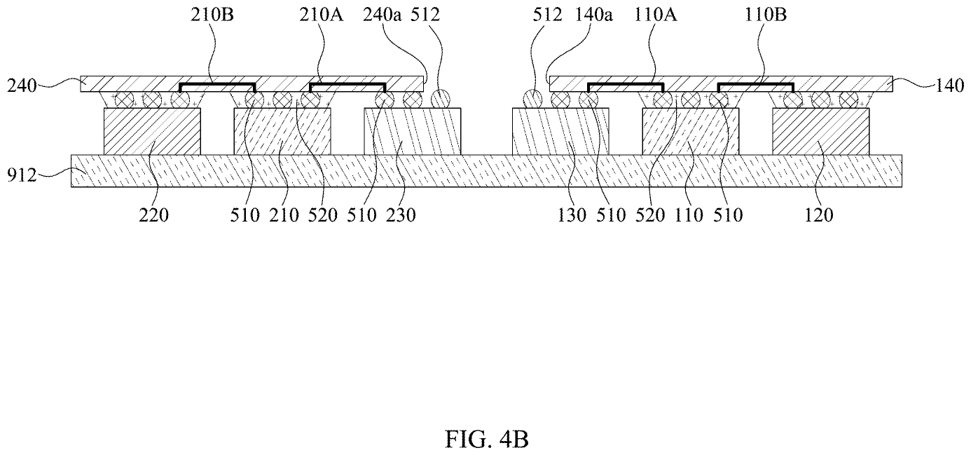

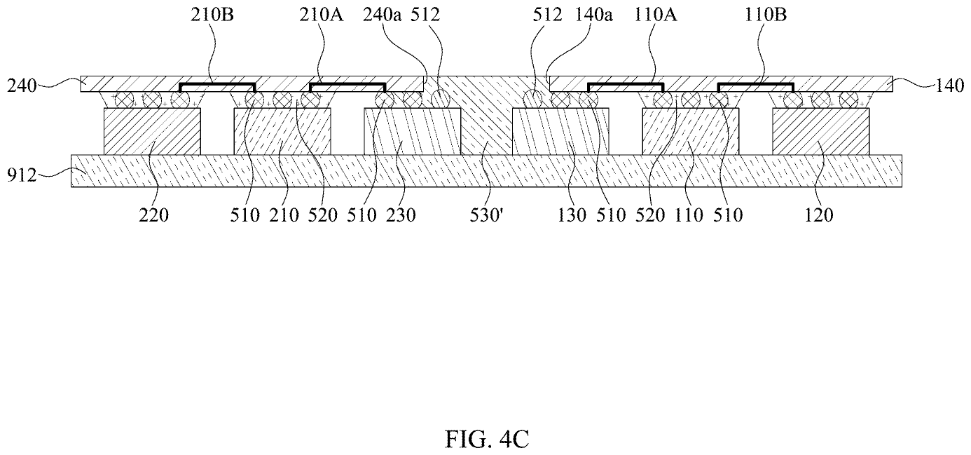

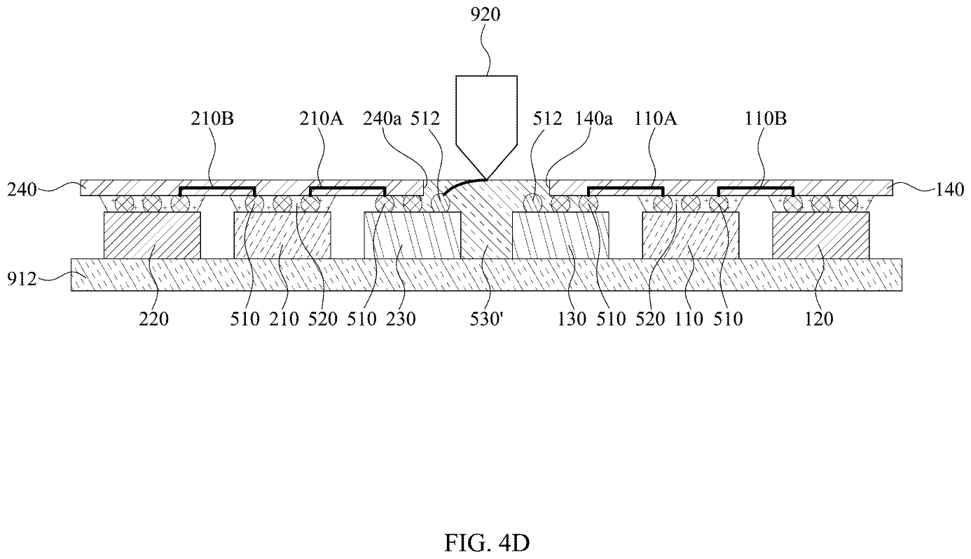

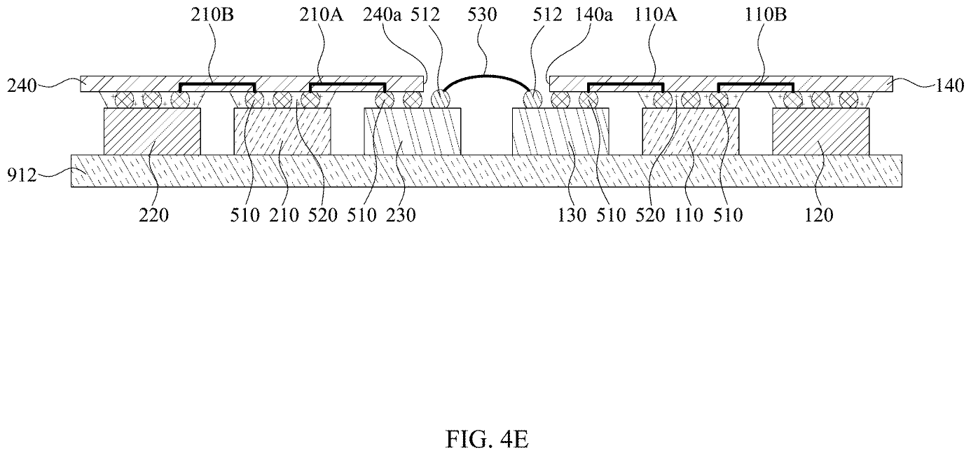

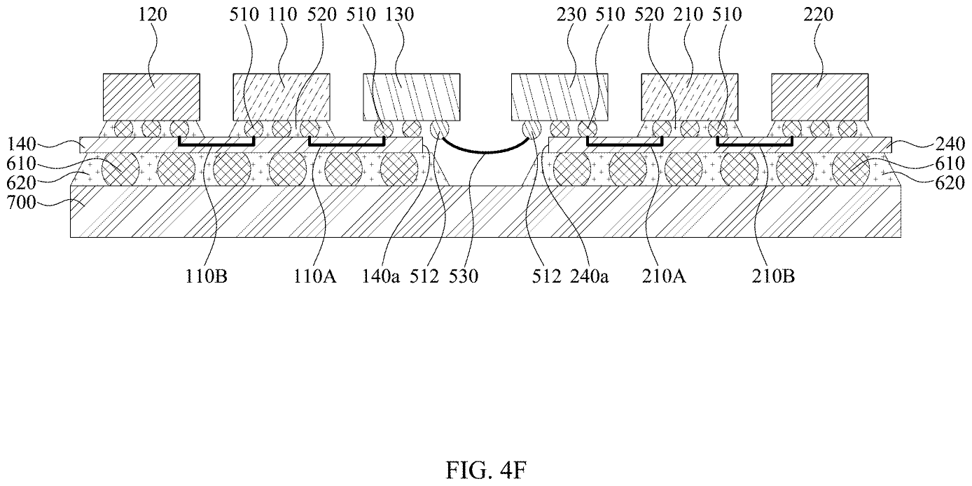

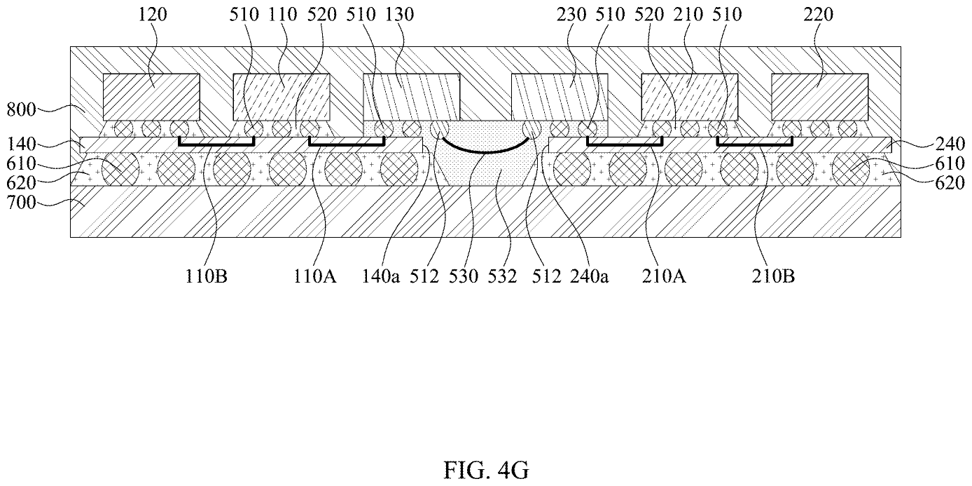

FIG. 4A, FIG. 4B, FIG. 4C, FIG. 4D, FIG. 4E, FIG. 4F and FIG. 4G illustrate various stages of a method for manufacturing the semiconductor package 2 in accordance with some arrangements of the present disclosure.

As shown in FIG. 4A, the substrate 140 and the substrate 240 may be disposed on a carrier 910. The substrate 140 and the substrate 240 may be temporarily bonded to the carrier 910, for example, by a temporary bonding material such as a temporary bonding adhesive (not shown). The electronic elements 110, 120, 210 and 220 each may be provided with connectors 510 (e.g., metal bumps). The electronic elements 130 and 230 each may be provided with connectors 510 (e.g., metal bumps) and a connector 512 (e.g., an optical bump). The electronic elements 110, 120 and 130 may be disposed on the substrate 140. The electronic elements 110, 120 and 130 may be flip-chip bonded to the substrate 140 through the connectors 510. The electronic element 110 may be electrically connected to the electronic element 130 through an interconnection element 110A of the substrate 140. The electronic element 110 may be electrically connected to the electronic element 120 through an interconnection element 110B of the substrate 140. The electronic element 130 may have an overhang 130h relative to the substrate 140 (or the surface 140a of the substrate 140). The connector 512 of the electronic element 130 is located at the overhang 130h. The electronic elements 210, 220 and 230 may be disposed on the substrate 240. The electronic elements 210, 220 and 230 may be flip-chip bonded to the substrate 240 through the connectors 510. The electronic element 210 may be electrically connected to the electronic element 230 through an interconnection element 210A of the substrate 240. The electronic element 210 may be electrically connected to the electronic element 220 through an interconnection element 210B of the substrate 240. The electronic element 230 may have an overhang 230h relative to the substrate 240 (or the surface 240a of the substrate 240). The connector 512 of the electronic element 230 is located at the overhang 230h. A filling structure 520 (e.g., an underfill structure) may be formed between the electronic element 110 and the substrate 140, between the electronic element 120 and the substrate 140, between the electronic element 210 and the substrate 240, and between the electronic element 220 and the substrate 240 to cover the connectors 510. The filling structure 520 may be formed by dispensing and curing an underfill material.

As shown in FIG. 4B, the semiconductor package shown in FIG. 4A may be reversed and temporarily bonded to another carrier 912. The electronic elements 110, 120, 130, 210, 220 and 230 may be temporarily bonded to the carrier 912, for example, by a temporary bonding material such as a temporary bonding adhesive (not shown). The carrier 910 may be removed from the substrates 140 and 240, for example, by a debonding process, to expose the connectors 512.

As shown in FIG. 4C, a photoresist material 530′ may be disposed between the electronic element 130 and the electronic element 230. The photoresist material 530′ may cover the connector 512 of the electronic element 130 and the connector 512 of the electronic element 230. The photoresist material 530′ may cover at least a part of the electronic element 130 and at least a part of the electronic element 230. The photoresist material 530′ may fill a gap between the substrate 140 and the substrate 240. The photoresist material 530′ may include or be a negative photoresist material. The photoresist material 530′ may include a resin (e.g., an epoxy resin, such as bisphenol A novolac epoxy), a photosensitive compound (e.g., a photoacid generator) and a solvent (e.g., an organic solvent).

As shown in FIG. 4D, an energy beam (e.g., laser beam) 920 may be applied onto the photoresist material 530′ to form a pattern (i.e., a structure of an interconnection element) in the photoresist material 530′. The laser beam 920 may be a pulsed laser beam. The laser beam 920 may be referred to as a lithography beam. The photoresist material 530′ may be cured by the laser beam 920 through two-photon polymerization. The focus of the laser beam 920 may be adjusted so as to define a structure of an interconnection element (such as an interconnection element 530 shown in FIG. 4E) in the photoresist material 530′.

As shown in FIG. 4E, an uncured part of the photoresist material 530′ may be removed by a developer to form an interconnection element 530 connecting the connector 512 of the electronic element 130 and the connector 512 of the electronic element 230.

As shown in FIG. 4F, the semiconductor package shown in FIG. 4E may be flip-chip bonded to a base 700 through connectors 610. A filling structure 620 (e.g., an underfill structure) may be formed between the substrate 140 and the base 700 and between the substrate 240 and the base 700 to cover the connectors 610. The filling structure 620 may be formed by dispensing and curing an underfill material. The carrier 912 may be removed, for example, by a debonding process.

As shown in FIG. 4G, a cladding material 532 may be disposed to cover or surround interconnection element 530. The cladding material 532 may have a lower refractive index than the interconnection element 530. The cladding material 532 may cover or surround the connectors 510 and 512 of the electronic elements 130 and 230. An encapsulant 800 may be disposed to cover the electronic elements 110, 120, 130, 210, 220, 230, the cladding material 532 and the filling structure 520.

Spatial descriptions, such as “above,” “below.” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of the arrangements of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to =0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially parallel” can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to =0.5°, less than or equal to ±0.1°, or less than or equal to ±0.05°. For example, “substantially perpendicular” can refer to a range of angular variation relative to 90° that is less than or equal to ±10°, such as less than or equal to ±5°, less than or equal to ±4°, less than or equal to ±3º, less than or equal to ±2°, less than or equal to ±1°, less than or equal to ±0.5°, less than or equal to ±0.1°, or less than or equal to ±0.05°. In addition, a first surface of an object is “substantially level” with a second surface of another object if the first surface and the second surface are at the same plane within a variation of ±10%, such as ±5%, ±4%, ±3%, ±2%, ±1%, ±0.5%, ±0.1% or ±0.05%, of a height/length of the object.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between the highest point and the lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

While the present disclosure has been described and illustrated with reference to specific arrangements thereof, these descriptions and illustrations are not limiting. It should be understood by those skilled in the art that various changes may be made, and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A semiconductor package, comprising:
a first electronic element disposed over a first substrate, the first electronic element extending beyond an edge of the first substrate;
a second electronic element disposed over a second substrate spaced apart from the first substrate, the second electronic element extending beyond an edge of the second substrate and towards the first electronic element; and
a first interconnection element connected to the first electronic element and the second electronic element,
wherein the first interconnection element is configured to optically transmit a signal between the first electronic element and the second electronic element.

2. The semiconductor package of claim 1, wherein the first electronic element comprises a first optical bump and the second electronic element comprises a second optical bump, and wherein the first interconnection element is connected to the first optical bump and the second optical bump.

3. The semiconductor package of claim 2, wherein a projection of the first substrate in a vertical direction exposes the first optical bump, and/or a projection of the second substrate in a vertical direction exposes the second optical bump.

4. The semiconductor package of claim 1, wherein the first interconnection element has a small curvature.

5. The semiconductor package of claim 4, wherein a projection of the first or second substrate in a horizontal direction exposes the first interconnection element.

6. The semiconductor package of claim 1, further comprising a filling structure covering the first interconnection element, wherein the filling structure comprises a reflective material having a lower refractive index than the first interconnection element.

7. The semiconductor package of claim 6, wherein the filling structure fills in at least a part of a gap between the first electronic element and the second electronic element.

8. The semiconductor package of claim 1, further comprising a third electronic element disposed over the first substrate, wherein a signal transmission between the third electronic element and the first electronic element is in a way different from a signal transmission between the first electronic element and the second electronic element.

9. The semiconductor package of claim 8, wherein the third electronic element is electrically connected to the first electronic element through a second interconnection element of the first substrate.

10. The semiconductor package of claim 8, wherein a signal transmission path between the third electronic element and the first electronic element is shorter than a signal transmission path between the first electronic element and the second electronic element.

11. The semiconductor package of claim 1, wherein a length by which the first electronic element extends beyond the edge of the first substrate is different from a length by which the second electronic element extends beyond the edge of the second substrate.

12. A semiconductor package, comprising:
a first electronic element disposed over a substrate; and
a second electronic element disposed over the substrate,
wherein the first electronic element is electrically connected to the second electronic element through the substrate, and the first electronic element is non-electrically connected to an external element.

13. The semiconductor package of claim 12, wherein the first electronic element has an overhang extending beyond an edge of the substrate.

14. The semiconductor package of claim 13, wherein the overhang of the first electronic element is connected to the external element through a photonic bonding wire or an optical fiber.

15. A semiconductor package, comprising:
a first electronic element disposed over a first substrate;
a second electronic element disposed over a second substrate spaced apart from the first substrate;
a first interconnection element configured to optically transmit a signal between the first electronic element and the second electronic element; and
a cladding material encapsulates the first interconnection element and configured to confine light in the first interconnection element.

16. The semiconductor package of claim 15, wherein the first interconnection element is connected to a surface of the first electronic element facing the first substrate and a surface of the second electronic element facing the second substrate.

17. The semiconductor package of claim 16, wherein the cladding material covers at least a part of the surface of the first electronic element facing the first substrate and at least a part of the surface of the second electronic element facing the second substrate.

18. The semiconductor package of claim 15, further comprising a third electronic element disposed over the first substrate, wherein the third electronic element is electrically connected to the first electronic component through a second interconnection element of the first substrate.

19. The semiconductor package of claim 18, wherein a signal transmission path of the second interconnection element is shorter than a signal transmission path of the first interconnection element.

20. The semiconductor package of claim 15, wherein the cladding material is configured to reduce light leakage from the first interconnection element.
